(19) United States
(12) Patent Application Publication
(10) Pub. No.: US 2025/0343030 A1
(43) Pub. Date: Nov. 6, 2025

(54) PROCESSING CHAMBER AND METHOD FOR INTEGRATED ETCHING AND DEPOSITION

(71) Applicant: Applied Materials, Inc., Santa Clara, CA (US)

(72) Inventors: Zhepeng CONG, San Jose, CA (US); Xuebin LI, Sunnyvale, CA (US); Akhil MEHROTRA, Sunnyvale, CA (US)

(21) Appl. No.: 18/652,612

(22) Filed: May 1, 2024

(51) Int. Cl. H01J 37/32

(52) U.S. Cl. CPC H01J 37/32449; H01J 37/32715; H01J 37/32357; H01J 2237/20214; H01J 2237/332; H01J 2237/334

(57) ABSTRACT

Disclosed herewith are a showerhead, a processing chamber, and a method for growing an epitaxial layer. A body of the showerhead has a disk-shape. The body includes a separation section formed by a solid circular sector and a connecting section formed by another circular sector that have a plurality of conduits. The connecting section and the separation section are coplanar and non-overlapping. The processing chamber includes the showerhead, a first gas inlet configured to flow a deposition gas in a lateral direction to a first plenum under the showerhead; and a second gas inlet configured to flow an etchant gas to a second plenum above the showerhead. The plurality of conduits allow the etchant gas to flow in a direction from the first plenum to the second plenum. The method can simultaneously implement both a deposition process and an etching process in the processing chamber.

### BACKGROUND

### Field

The present disclosure relates to a processing chamber and method for an epitaxial deposition, and, more specifically, relates to a processing chamber and method capable of implementing a deposition process and an etching process simultaneously or in a cyclic sequence.

### Description of the Related Art

Epitaxy (EPI) has been widely used in depositing materials on surfaces of semiconductor substrates and devices. An EPI chamber is designed for an EPI deposition process. A deposition gas flows into a processing volume where a substrate is positioned on a susceptor. The deposition gas may reach the substrate and form an EPI layer. With the design of the semiconductor devices gets more and more complex, EPI layers may be deposited onto structures of high aspect ratios, such as fins or deep trenches.

The EPI growth of materials onto structures of high aspect ratios have several issues. For example, untargeted locations may experience the formation of isolated nodules on their surfaces. These isolated nodules can continue to grow and become contiguous. Both the isolated nodules and a contiguous layer can interfere with a subsequent process. In another observation, the rate of EPI growth may be slower in deeper locations than the rate at shallower locations. The faster growing rate at the shallower locations can cause a pinch-off in a trench, which can close off the trench at a shallower location and cause voids or cavities in the deeper locations.

An etch-back process may be implemented, which adds an etch process during the deposition process to remove any isolated nodules from non-targeted surfaces. The etch process and the deposition process are implemented in an alternate manner to prevent the isolated nucleation from growing. However, this etch-back process moves a substrate back and forth between an EPI chamber and an etch chamber, lowering the throughput. Thus, a need exists for an improved EPI processing chamber and method.

### SUMMARY

Disclosed herewith are a showerhead, a processing chamber, and a method for EPI growth. In an example, the showerhead includes a disk-shaped body having a center, which includes a separation section formed by a first circular sector that is solid; and a connecting section formed by a second circular sector and having a plurality of conduits. The connecting section and the separation section are coplanar and share a center. The separation section and the connecting section do not overlap with each other.

In another example, a processing chamber includes an upper window; a first plenum disposed under the upper window and configured to contain a first gas; a showerhead disposed under the first plenum; a second plenum disposed under the showerhead and configured to contain a second gas; and a susceptor disposed under the second plenum. The showerhead may be configured according to various embodiments of the present disclosure.

In another example, a processing chamber includes a showerhead facing a susceptor, a first gas inlet configured to flow a deposition gas in a lateral direction to a first plenum disposed between the showerhead and the susceptor; and a second gas inlet configured to flow an etchant gas to a second plenum disposed above the showerhead. The showerhead includes a plurality of conduits configured to flow the etchant gas in a direction toward the susceptor.

In another example, the method includes disposing a substrate on a susceptor disposed within a processing volume of the processing chamber; rotating the susceptor and the substrate; and causing a deposition process at a first zone of the processing volume while simultaneously causing an etching process at a second zone of the processing volume. The method may further includes separating a first plenum containing an etchant gas and a second plenum containing a deposition gas by a showerhead, the showerhead being configured according to various embodiments of the present disclosure; flowing the etchant gas into the first plenum at a first pressure level; flowing the deposition gas into the second plenum at a second pressure level lower than the first pressure level; and causing the etching gas to flow through a plurality of conduits from the first plenum into the second zone.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of an EPI processing chamber, according to an embodiment of the present disclosure.

FIG. 3A illustrates a schematic configuration of processing zones within a processing chamber, according to an embodiment of the present disclosure.

FIG. 3B illustrates a schematic configuration of a connecting section of a showerhead, according to an embodiment of the present application.

FIG. 4A illustrates a schematic bottom view of a showerhead having a separation section and a connecting section, according to an embodiment of the present disclosure.

FIG. 4B illustrates a schematic bottom view of a showerhead having a separation section, a connecting section, and a plurality of pump-out sections, according to an embodiment of the present disclosure.

FIG. 4C illustrates a schematic bottom view of a showerhead having a separation section, a plurality of pump-out sections, and a plurality of connecting sections according to an embodiment of the present disclosure.

FIG. 5 illustrates a schematic showerhead with a plurality of conduits in a connecting section, according to an embodiment of the present disclosure.

FIG. 6 illustrates a method for an EPI process, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein is an epitaxy (EPI) chamber capable of implementing epitaxial growth and an etch process simultaneously. The EPI chamber integrates a deposition zone and an etch zone in a common volume above a substrate. The deposition zone is configured for a deposition process, while the etch zone is configured for an etching process. The deposition zone and the etch zone are divided by separators in order to contain a deposition gas and an etchant gas, respectively. Other processing zones, such as pump-out zones, may be additionally included in the processing chamber. The deposition zone, the etch zone, and other processing zones are capable of being operated simultaneously. When a substrate is disposed inside the processing chamber and rotated by a susceptor, the substrate can be moved into different processing zones and subject to a cyclic etch-back process without the need to be moved out of the processing chamber.

In an example, the epitaxy chamber includes two gas plenums separated by the showerhead. The two gas plenums include a first gas plenum disposed above a second gas plenum. The first gas plenum is configured to contain an etchant gas, while the second gas plenum is configured to contain a deposition gas. The showerhead includes a separation section that overlaps with the deposition zone. The separation section is configured to prevent the two process gases from mixing with each other. The showerhead also includes a connecting section that overlaps with the etch zone. The connecting section is configured to allow the etchant gas to enter the second plenum from the first plenum. The first plenum may have a higher pressure than the second plenum such that the etchant gas can be accelerated into the second plenum, generating a more directional etch effect.

In another example, the connecting section of the showerhead includes a plurality of conduits whose size and pattern are configured to counter a depletion effect caused by an exhaust outlet. An RF electrode may be disposed around the showerhead for energizing the etchant gas in the first plenum. A remote plasma source may also be used to energize the etchant gas.

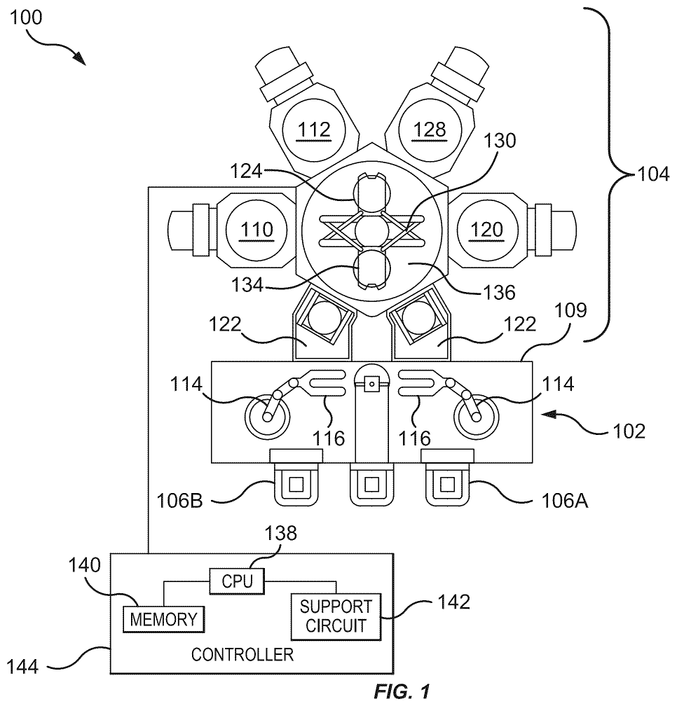

FIG. 1 illustrates a schematic top view of a processing system 100 for processing a substrate, according to one or more embodiments. In an embodiment, the processing system 100 is configured to implement an epitaxial growth method and system according to various embodiments of the present disclosure. The processing system 100 includes a processing platform 104 coupled with a factoring interface 102 and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, one or more load lock chambers 122, and a transfer chamber 136 that is coupled to the one or more load lock chamber 122. The plurality of processing chamber 110 may include a plasma enhanced chemical vapor deposition (PECVD) chamber, an epitaxy (EPI) chamber, a rapid thermal processing (RTP) chamber, a reactive ion etching (RIE) chamber, or other suitable chamber. The transfer chamber 136 can be maintained under vacuum, or can be maintained at an ambient (e.g., atmospheric) pressure. Two load lock chambers 122 are shown in FIG. 1.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

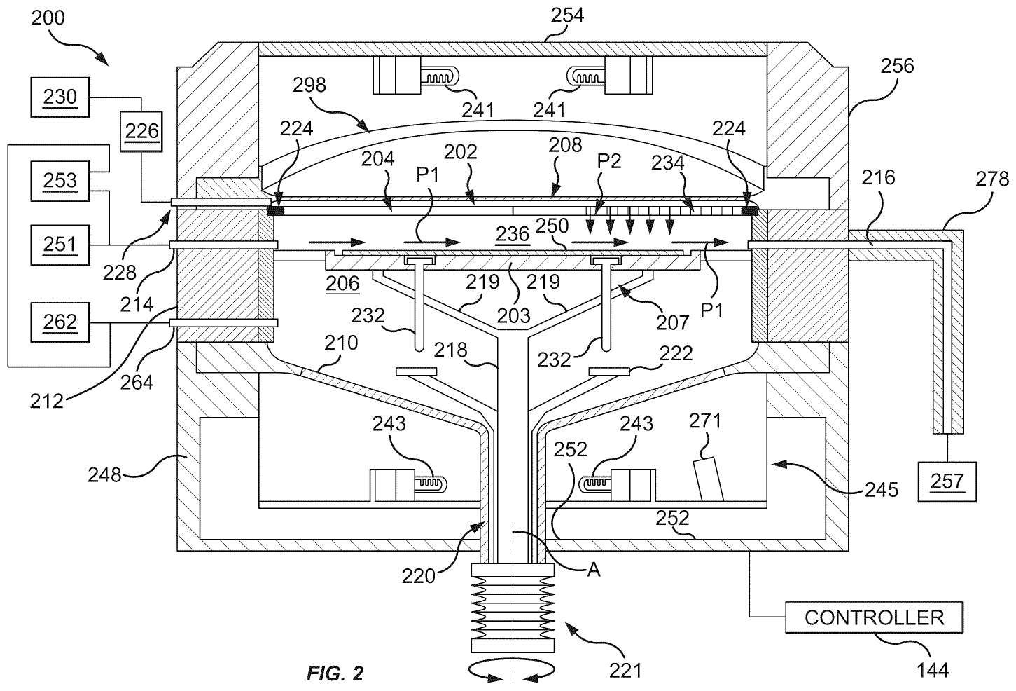

FIG. 2 illustrates a schematic cross-sectional view of an EPI processing chamber 200 according to an embodiment. The EPI processing chamber 200 functions as a deposition chamber to grow an EPI layer onto fins or trenches of a substrate according to various embodiments of the present disclosure. One or more of the processing chambers 110, 112, 128 shown in FIG. 1 can be configured as the processing chamber 200.

The processing chamber 200 includes an upper body 256, a lower body 248 disposed below the upper body 256, and a flow module 212 disposed between the upper body 256 and the lower body 248. The upper body 256, the flow module 212, and the lower body 248 form a chamber body. Disposed within the chamber body is a susceptor 203 disposed on a substrate support assembly 206, an upper window 211 (such as an upper dome), a lower window 210 (such as a lower dome), a plurality of upper heat sources 241, and a plurality of lower heat sources 243. As shown, the controller 144 is in communication with the processing chamber 200 and is used to control processes and methods of at least the processing chamber 200.

The plurality of upper heat sources 241 are disposed between the upper window 211 and a lid 254. The plurality of upper heat sources 241 form a portion of the upper heating module 255. The plurality of lower heat sources 243 are disposed between the lower window 210 and a chamber floor 252. The plurality of lower heat sources 243 form a portion of a lower heating module 245. The upper window 211 is an upper dome and is formed at least partially of an energy transmissive material, such as quartz. The lower window 210 is a lower dome and is formed at least partially of an energy transmissive material, such as quartz.

The processing chamber 200 includes one or more thermal sensors 271 configured to detect a thermal condition of the processing chamber 200. The one or more thermal sensors 271 may include one or more cameras, one or more pyrometers, one or more thermoelectric sensors, and/or one or more thermal labels. The one or more thermal sensors 271 can be mounted, for example, below the lower window 210 (as shown in FIG. 2), or above the upper window 211 (such as on or in the lid 254), or any other suitable place in the processing chamber 200. In one example, a pyrometer is mounted above the upper window 211 and is configured to remotely measure temperature of the substrate 250 and the substrate support assembly 206 during the growth process of an EPI layer.

The substrate support assembly 206 is disposed between the upper window 211 and the lower window 210. The substrate support assembly 206 supports the substrate 250 and is configured to rotate the substrate 250 during a process. The substrate support assembly 206 is supported by an inner shaft 218 coupled with a motion assembly 221. The motion assembly 221 includes one or more actuators and/or adjustment devices that provide movement and/or adjustment for the inner shaft 218, which, in turn, moves the substrate support assembly 206 and the substrate 250. The substrate support assembly 206 is coupled to the inner shaft 218 through one or more arms 219. A plurality of lift pin holes 207 are disposed in the substrate support assembly 206 and sized to accommodate a lift pin assembly 232 that is used to lift the substrate 250 from the substrate support assembly 206. The lift pin assembly 232 is coupled with the actuator 221 via pedestals 222 of an outer shaft 220.

In an embodiment, the processing chamber 200 includes a first plenum 202 configured to contain an etchant gas P2 and a second plenum 236 configured to contain a deposition gas P1. The first plenum 202 and the second plenum 236 are separated by a showerhead 204 and form a processing volume inside the processing chamber 200. The first plenum 202 is disposed between a containing plate 208 and the showerhead 204. In an embodiment, the containing plate 208 is coupled to the upper body 256 and may be made of a material similar as that of the upper dome 298. In another embodiment, the containing plate 208 may be part of the showerhead 204. The second plenum 236 is disposed between the showerhead 204 and the substrate support assembly 206. The showerhead 204 is configured to allow the etchant gas P2 to flow from the first plenum 202 into the second plenum 236 at a connecting section 234. As a result, the substrate 250 can be subject to a deposition process and an etch process simultaneously, albeit at different locations. As the processing chamber 200 is capable of implementing a deposition process and an etch process simultaneously, the deposition gas P1 and the etchant gas P2 may be flowed into the first plenum 202 and the second plenum 236 simultaneously.

In an embodiment, additional processing zones may be formed in the processing chamber. The additional processing zones may include a pump-out zone for pumping out effluent gases, a clean zone for cleaning the substrate, or other processing zone. The showerhead 204 may remain stationary while the substrate support assembly 206 rotates. As an area of the substrate 250 can enters into various processing zones in a cyclic manner.

In an embodiment, the showerhead 204 may be divided into a plurality of sections. In an embodiment, the plurality of sections are coplanar. Each section corresponds to a processing zone and is configured to effect a dedicated process, such as a deposition process, an etch process, or a pump-out process. For example, the showerhead 204 may include a separation section being substantially solid to prevent process gases in the two plenums 202, 236 from mixing with each other. The showerhead 204 may also include a connecting section having a plurality of conduits configured to allow the etchant gas P2 to enter the etch zone from the first plenum 202. The first plenum 202 has a higher pressure level than the second plenum 236 such that the etchant gas P2 may be accelerated from the first plenum 202 toward the substrate 250. For example, the pressure level of the first plenum 202 may be set to be between 200 to 400 Torr. The pressure level of the second plenum 236 may be set to be between 0.1 to 50 Torr. Details of the showerhead 204 will be provided in the following part of the present disclosure when referring to other drawings. In an embodiment, the showerhead 204 is made of an energy transmissive material, such as quartz.

In an embodiment, an RF electrode 224 is disposed around the showerhead 204. The RF electrode 224 is configured to energize the etchant gas P2. The RF electrode may be made of silicon carbide, aluminum, or any other suitable material. A remote plasma source 226 may also be used to energize the etchant gas P2.

The flow module 212 includes a plurality of deposition gas inlets 214, a plurality of purge gas inlets 264, a plurality of etchant gas inlets, and one or more gas exhaust outlets 216. The deposition gas inlets 214 are connected with a plurality of deposition gas sources 251, 253 and provides a cross-flow of precursors across the substrate 250 in the second plenum 236. The etchant gas inlets 228 are connected with an etchant gas source 230 and the remote plasma source 226. The etchant gas inlets 228 provides the etchant gas P2 into the first plenum 202. The etchant gas may include a chlorine based gas, such as HCL or Cl₂. The etchant gas may also include hydrogen H₂. The purge gas inlets 264 are connected to a purge gas source 262 and provide purge gas to the EPI chamber 200. The gas exhaust outlets 216 are connected to an exhaust system 278 and an exhaust pump 257. The exhaust system 278 is disposed on an opposite side of the processing chamber 200 relative to the flow module 212 and configured to pump out the effluent gases from the processing chamber 200.

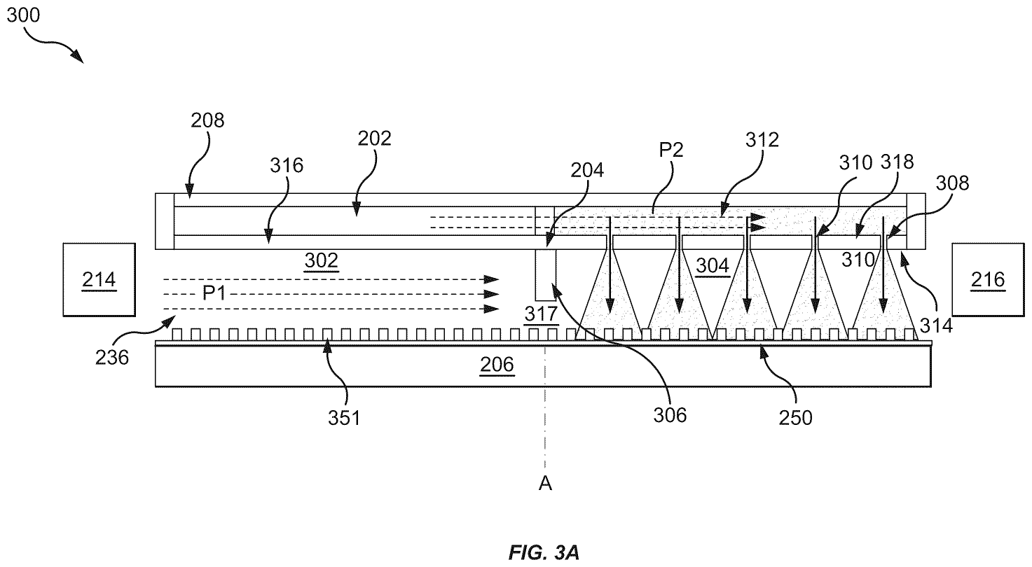

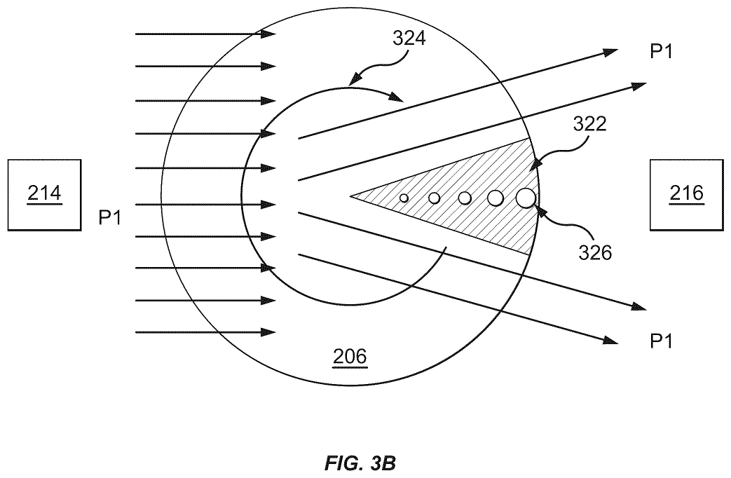

FIG. 3A illustrates a schematic configuration 300 of various processing zones in the processing chamber 200, according to an embodiment of the present disclosure. As shown in FIG. 3, the substrate 250 is disposed on the substrate support assembly 206 in the second plenum 236. The substrate 250 has structures 351 of a high aspect ratio, such as trenches and/or fins formed on the surface of the substrate 250. The second plenum 236 is separated into a plurality of processing zones, such as a deposition zone 302, an etch zone 304, or any other zone, each zone being configured to implement a dedicated process. For example, the deposition zone 302 implements a deposition process, and the etch zone implements an etching process.

In an embodiment, one or more separators 306 may be disposed in the second plenum 236 for separating the processing zones. The separators 306 may be disposed along the boundaries of the processing zones and are configured to confine a processing gas in a designated processing zone. The separators 306 may be an independent structure or be part of the showerhead 204. In an embodiment, the separator 306 may extend from a bottom surface 314 of the showerhead 204. A gap 317 may be formed between the separator 306 and the substrate support assembly 206 to allow effluent gases generated by a processing zone to be pumped out via the exhaust outlet 216.

In an example, a deposition zone 302 is disposed adjacent to the deposition gas inlet 214. The deposition gas P1 is configured to flow from the deposition gas inlet 214 directly into the deposition zone 302. The deposition gas P1 may flow in a lateral direction that is substantially parallel to the substrate 250. The deposition gas P1 enters the deposition zone 302 from a location that is under the showerhead 204. The showerhead 204 includes a separation section 316 that is positioned above the processing zone 302. The separation section 316 substantially overlaps with the processing zone 302. The separation section 316 does not allow the deposition gas P1 to escape or other processing gas to enter the deposition zone. In an embodiment, the separation section 316 may be a solid part without any through holes. The deposition gas P1 forms an EPI layer on the fins/trenches 351. The effluent gas generated by the EPI process can be vacuumed to the exhaust outlet 216 via the gap 317.

In an example, an etch zone 304 is formed in the second plenum 236 downstream of the flow of the deposition gas P1. In an embodiment, the etch zone 304 is disposed adjacent to the exhaust outlet 216. The etch zone 304 may be separated from the deposition zone 302 by the separators 306. To create the etch zone 304, the etchant gas P2 flows into the first plenum 202 at a location that is above the showerhead 204. When the etchant gas P2 reaches a connecting section 318 of the showerhead 204, the etchant gas P1 can flow into the etch zone 304 via a plurality of conduits 308. The plurality of conduits 308 may be slits, holes, or any other shape. The connecting section 318 is disposed above and overlaps with the etch zone 304. In an embodiment, the first plenum 202 has a higher pressure level than the etch zone 304. The pressure difference between the first plenum 202 and the etching zone 304 can accelerate the etchant gas P2 along a vertical direction 310 toward the substrate 250, thus helping the etchant gas P2 to penetrate any fluid boundary layers around the surfaces of the fins/trenches 351. The accelerated etchant gas P2 can also generate a more directional etch effect.

As shown in FIG. 3A, the separation section 316 and the connecting section 318 of the showerhead 204 are coplanar with each other. The separation section 316 and the connecting section 318 do not overlap. In an embodiment, the showerhead 204 is shaped like a disk, and the separation section 316 and the connecting section 318 occupy non-overlapping circular sectors of the disk.

As the substrate support assembly 206 rotates the substrate 250 around the axis A, each fin/trench 351 will enter the plurality of zones 302, 304 cyclically and be subject to various processes cyclically. In an embodiment, each fin/trench 351 is subject to alternating deposition and etching processes. In an embodiment, a pump-out zone is added between a deposition zone and an adjacent etch zone. As a result, each fin/trench 351 is subject to a deposition process, then a pump-out process, then an etching process. The additional pump-out zone helps removing byproducts generated by a prior process and provides a fresh start to a subsequent process. Other processing zones may be additionally included in the second plenum 236.

In an embodiment, the showerhead 204 is substantially circular. Each processing zone is formed substantially by a circular sector of the showerhead 204 and shares a center with each other and the showerhead 204. The etch zone 304 is configured to be smaller than the deposition zone 302 because the etching process functions as an auxiliary process to assist an EPI growth in the fins/trenches 351. The etching rate of the etch zone 304 can be controlled by several factors, such as temperature, plasma power, the pressure difference between the first plenum 202 and the second plenum 236, the rotation speed of the substrate support assembly 206, and other suitable parameters. The shape of a circular sector can help the etch zone 304 to counter the depletion effect at locations adjacent to the exhaust outlet 216.

FIG. 3B illustrates a schematic bottom view of an auxiliary showerhead 322, according to an embodiment of the present disclosure. The substrate support assembly 206 is rotated in a counterclockwise direction 324. The deposition gas P1 flows in a lateral direction that is parallel to the surface of the substrate support assembly 206. In an embodiment, the auxiliary showerhead 322 is shaped like a circular sector (a slice of pizza) and disposed adjacent to the exhaust outlet 216. The auxiliary showerhead 320 may be disposed under an existing showerhead for deposition and form an etch zone. The auxiliary showerhead 320 includes a plurality conduits 326 configured to direct the etching gas P2 (not shown) toward the substrate support assembly 206. The plurality of conduits 326 may be the same size or different sizes. In an embodiment, the sizes of the conduits 326 increase when they are getting closer to the exhaust outlet 216. When the deposition gas P1 flows from the deposition gas inlets 214 to the exhaust gas outlet 216, the deposition gas P1 can be pushed sideways by the auxiliary showerhead 322, which form the etch zone for etching the substrate disposed on the substrate support assembly 206.

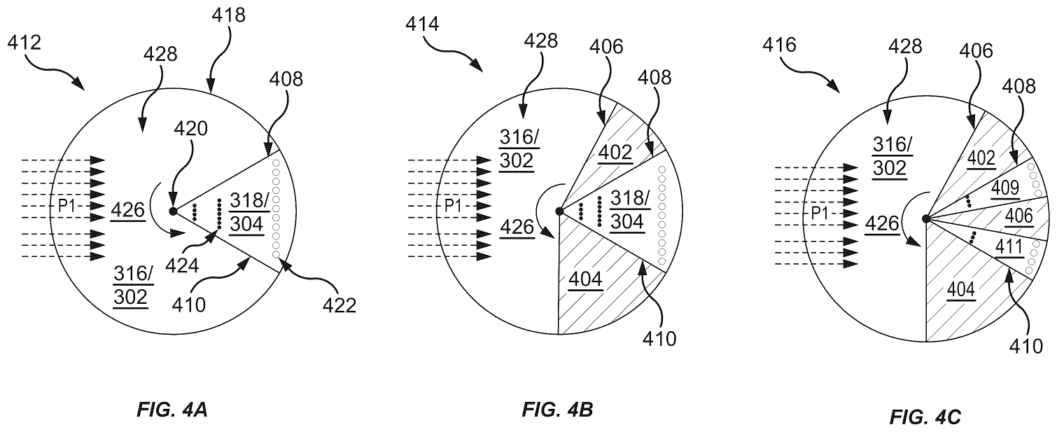

FIGS. 4A-C illustrate various showerheads having a plurality of processing zones, according to various embodiments of the present disclosure. The showerhead 204 in FIG. 3 may be configured as the showerheads 412, 414, and 416 of FIGS. 4a-c. The deposition gas P1 in FIGS. 4a-c flows from left to right. The substrate support assembly 206 rotates in a counterclockwise direction in FIGS. 4a-c.

FIG. 4A illustrates a schematic bottom view of a showerhead 412 having a separation section 316 and a connecting section 318. The deposition gas P1 flows from left to right. The showerhead 412 is substantially circular having a disk-shaped body 428, which has an outer perimeter 418 and a center 420. The connecting section 318 may occupy a circular sector of the disk-shaped body 428 and have a central angle of about 30 to 90 degrees. The connecting section 318 is positioned at the downstream of the deposition gas P1. The connecting section 318 includes a plurality of conduits 308 (shown in FIG. 3). The plurality of conduits 308 includes a first group of conduits 422 that are placed adjacent to the exhaust outlet 216 (shown in FIG. 3) and a second group of conduits 424 that are placed adjacent to the center 420. The conduits 422 may have a larger cross-sectional area than that of the conduits 424 to counter the depletion effect caused by the exhaust outlet 216.

The separation section 316 may occupy the rest circular sector of the disk-shaped body 428. The separation section 316 is positioned upstream of the deposition gas P1. The separation section 316 and the connecting section 318 share the center 420. Two separators 408 and 410 are disposed along the perimeter of the etch zone 304 to separate the etch zone 304 from the deposition zone 302. In an embodiment, the separators 408 and 410 extend from the center 420 to the outer perimeter 418. The separators 408 and 410 also extend away from the bottom surface 314 (shown in FIG. 3) of the disk-shaped body 428 toward the substrate 250 (shown in FIG. 3).

FIG. 4b illustrates a schematic bottom view of a showerhead 414 having a separation section 316, a connecting section 318, a first pump-put section 402, and a second pump-out section 404. The pump-out sections 402 and 404 are disposed between the separation section 316 and the connecting section 318: one downstream and one upstream of the rotation direction 426 of the substrate, respectively. The first pump-out section 402 is configured to form a pump-out zone to flow effluent gas generated by the etch zone 304 to the exhaust outlet 216. The first pump-out section 402 abuts the separation section 316 and the connecting section 318. The second pump-out section 404 is configured to form a second pump-out zone to flow effluent gas generated by the deposition zone 302 to the exhausting outlet 216. In an embodiment, the first pump-out section 402 has a smaller central angle than the second pump-out section 404 because the etch zone is smaller than the deposition zone. The second pump-out section 404 also abuts the separation section 316 and the connecting section 318 and is separated from the first pump-out section 402 by the separation section 316.

FIG. 4c illustrates a schematic bottom view of a showerhead 416 having a separation section 316, two (2) connecting sections 409, 411, and a plurality of pump-out sections 402, 404, 406. Comparing with FIG. 4b, the showerhead 416 separates the connecting section 318 into two connecting sections 411 and 409 and adds a third pump-out section 406 between the two connecting sections 411 and 409.

It is contemplated that additional deposition zones, pump out zones, and etch zones may be included in a showerhead of the present disclosure. Other processing zones, such as a cleaning zone, a dry zone, or other suitable zone, may also be included in the showerhead. The plurality of zones are capable of implement various processing in a processing chamber simultaneously.

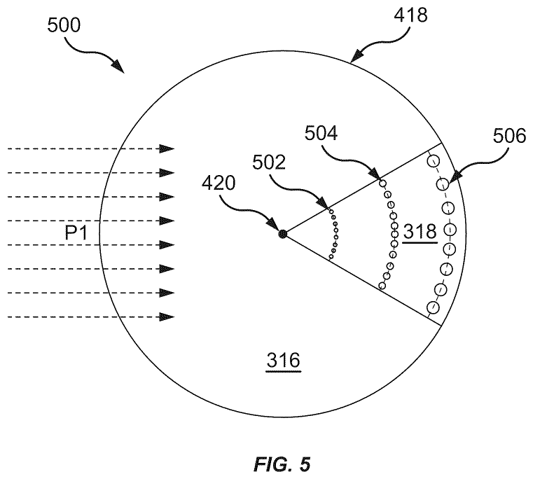

FIG. 5 illustrates a configuration of a connecting section of a showerhead, according to an embodiment. The connecting section 318 of a showerhead 500 has a plurality of conduits 502, 504, 506. Comparing with the conduits shown in FIGS. 4a-c, which are arranged in straight lines, the conduits 502, 504, 506 of FIG. 5 are concentrically arranged along a plurality of arcs having the center 420. In an embodiment, the diameter of the conduits may gradually increase from the center 420 to the outer perimeter 418. For example, the conduits 502 are closer have a smaller diameter than the conduits 504, which have a smaller diameter than the conduits 506. In an embodiment, the plurality of conduits 502, 504, 506 have the same diameter with different spacing. For example, conduits 502, 504, and 506 are disposed along different circles around the center 420, in which the diameter of the conduits 502 is the smaller than that of the conduits 504, whose diameter is smaller than that of the conduits 506. As a result, the spacing between adjacent conduits 502 is larger than that of the adjacent conduits 504, whose spacing is larger than that of the conduits 506. The tighter packed conduits 506 are configured to counter the higher pressure because they are closer to the pump.

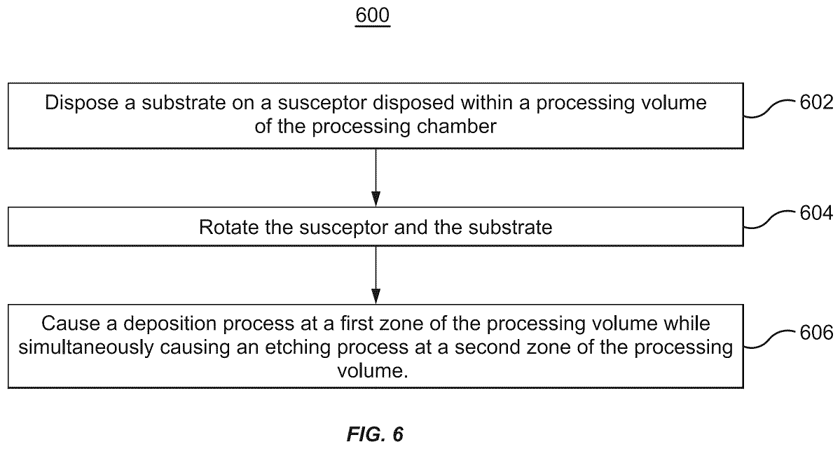

FIG. 6 illustrates a method for an EPI growth in a processing chamber, according to an embodiment. At operation 602, a substrate is disposed on a susceptor of a substrate support assembly placed in the processing volume of a processing chamber. At operation 604, an actuator assembly rotates the susceptor and the substrate. At operation 604, both the deposition gas and the etchant gas are provided to the processing chamber. The deposition gas is provided to a deposition zone, while the etchant gas is provided to an etch zone. The method causes the deposition zone to implement a deposition process to grow an EPI layer. Simultaneously, the method causes the etch zone to implement an etching process to remove isolated nodules deposited on untargeted locations.

In another embodiment, the operation 604 may cause the etching process and the deposition process to occur sequentially. When the deposition zone and the etch zone have a large pressure different, it may beneficial to avoid implementing the two processes simultaneously. The process gas P1 and the etchant gas P2 may be supplied sequentially to each processing zone of the showerhead such that the deposition or etch processes occur sequentially.

In various embodiments, the method further separating a first plenum containing the etchant gas and a second plenum containing the deposition gas by a showerhead. The showerhead is disposed above the susceptor and includes a separation section formed by a first circular sector and configured to be solid, the first circular sector being disposed above the first zone; and a connecting section formed by a second circular sector and having a plurality of conduits connecting the first plenum and the second plenum. The connecting section is disposed above the second zone. The connecting section and the separation section share a center. The method may further include flowing the etchant gas into the first plenum at a first pressure level; flowing the deposition gas into the second plenum at a second pressure level lower than the first pressure level; and causing the etching gas to flow through the plurality of conduits from the first plenum into the second zone.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A processing chamber for epitaxial growth, comprising:
a showerhead facing a substrate support assembly;
a first gas inlet configured to flow an etchant gas to a first plenum disposed above the showerhead;
a second gas inlet configured to flow a deposition gas in a lateral direction to a second plenum disposed between the showerhead and the substrate support assembly; and
wherein the showerhead comprises a plurality of conduits configured to flow the etchant gas from the first plenum to the second plenum in a direction toward the substrate support assembly.

2. The processing chamber of claim 1, wherein the showerhead comprises a disk-shaped body having a center, and the disk-shaped body further comprises:
a separation section comprising a first circular sector that is solid; and
a connecting section comprising a second circular sector and the plurality of conduits, wherein the connecting section is coplanar and non-overlapping with the separation section.

3. The processing chamber of claim 2, wherein a pressure level of the first plenum is higher than that of the second plenum.

4. The processing chamber of claim 2, further comprising:
an exhaust outlet configured to remove effluent gases from the processing chamber,
wherein the connecting section of the showerhead is disposed adjacent to the exhaust outlet.

5. The processing chamber of claim 2, wherein the showerhead comprises a separator disposed along a radius of the connecting section, and the separator extends from a bottom surface of the disk-shaped body toward the substrate support assembly.

6. The processing chamber of claim 2, further comprising a pump-out section comprising a third circular sector and abutting the connecting section and the separation section.

7. The processing chamber of claim 2, wherein the plurality of conduits include a first conduit disposed adjacent to the center and a second conduit disposed adjacent to an outer perimeter of the disk-shaped body, and the first conduit has a smaller cross-sectional area than the second conduit.

8. The processing chamber of claim 1, further comprising an RF electrode disposed around an outer perimeter of the showerhead and configured to energize the etchant gas.

9. A showerhead for a processing chamber, comprising:
a disk-shaped body having a center and comprising:
a separation section comprising a first circular sector that is solid; and
a connecting section comprising a second circular sector and a plurality of conduits, wherein the connecting section is coplanar and non-overlapping with the separation section.

10. The showerhead of claim 9, further comprising a separator disposed along a radius of the connecting section.

11. The showerhead of claim 10, wherein the separator extends away from a bottom surface of the disk-shaped body.

12. The showerhead of claim 9, wherein disc-shaped body is made of quartz.

13. The showerhead of claim 9, further comprising a first pump-out section comprising a third circular sector and abutting the connecting section and the separation section.

14. The showerhead of claim 13, comprising a second pump-out section comprising a fourth circular sector and separated from the first pump-out section by the separation section.

15. The showerhead of claim 14, wherein the second pump-out section and the second pump-out section have different sizes.

16. The showerhead of claim 9, wherein the connecting section has a smaller central angle than the separation section.

17. The showerhead of claim 9, wherein the plurality of conduits include a first conduit disposed adjacent to the center and a second conduit disposed adjacent to an outer perimeter of the showerhead, and the first conduit has a smaller cross-sectional area than the second conduit.

18. A method of growing an epitaxial layer in a processing chamber, comprising:
disposing a substrate on a susceptor of a substrate support assembly disposed within a processing volume of the processing chamber;
rotating the susceptor and the substrate; and
causing a deposition process at a first zone of the processing volume while simultaneously causing an etching process at a second zone of the processing volume.

19. The method of claim 18, further comprising:
separating a first plenum receiving an etchant gas and a second plenum receiving a deposition gas by a showerhead, wherein the showerhead is disposed above the susceptor and comprises a plurality of conduits;
flowing the etchant gas into the first plenum at a first pressure level;
flowing the deposition gas into the second plenum at a second pressure level lower than the first pressure level; and
causing the etchant gas to flow through the plurality of conduits from the first plenum into the second zone.

20. The method of claim 19, further comprising
forming a third zone in the processing volume for pumping out effluent gases of the deposition process or the etching process, the third zone being disposed between the first zone and the second zone.
